(19) United States
(12) Patent Application Publication
(10) Pub. No.: US 2013/0342188 A1
(43) Pub. Date: Dec. 26, 2013

(54) Disassociated Split Sensor Coil for Power Distribution Line Monitoring

(71) Applicant: Michael Wayne McKinley, Xenia, OH (US)

(72) Inventor: Michael Wayne McKinley, Xenia, OH (US)

(73) Assignee: GRID SENTRY LLC, Beavercreek, OH (US)

(21) Appl. No.: 13/529,854

(22) Filed: Jun. 21, 2012

(51) Int. Cl. G01R 1/20; G01R 3/00

(52) U.S. Cl. 324/126; 29/595

(57) ABSTRACT

A disassociated split sensor coil manufactured from hemi-toroidal cores. Each core includes a surface channel extending from end to end, with wire sections being wound about the core to form a helical sensor coil electrically connected to a connecting wire returned through the surface channel. The connecting wires are interconnected to form a continuous electrical path, with terminal wires being electrically connectable to a monitoring circuit. Also, a method of manufacturing including obtaining a hemi-toroidal core having a surface channel, placing a first length of a wire within the surface channel so as to extend from end to end, winding a second length of the wire so as to form a helical coil section extending from end to end, providing a third length of the wire extending from one end, and repeating the steps to form a disassociated split sensor coil electrically connectable by joining the first lengths of wire.

### FIELD

The subject matter described herein generally relates to electromagnetic sensor coils and, in particular, to a disassociated split electrical current sensor coil adapted for installation over live power distribution lines in an AC electrical power grid.

### BACKGROUND

Electrical current sensors are frequently installed on electrical transmission or distribution lines in regional electrical power grids in order to support power line monitoring and power management activities. The sensors are typically installed upon a transmission or distribution line and combined with a remote terminal unit (RTU) or similar communications device in order to report current flow to a monitoring station run by the grid operator. The sensed current flow or line dynamics, along with other sensed information such as line voltage, frequency, temperature, and the like, are used by the grid operator to configure and manage the network of transmission lines that interconnects remote electrical generation stations with local power distribution substations. Similar electrical current sensors are also incorporated into protective relay circuits that safeguard high value electromechnical equipment, such as arc furnaces, motors, and generators and identify electrical faults. The sensors are typically installed during connection of the equipment to an on-site transformer and/or busbar connections to local power distribution lines, or during later investigations of such connections in response to an electrical fault. The sensed current flow is used to actuate a relay to break the equipment power circuit if there is an overcurrent condition (indicating, for example, a potential short circuit) or, in some circuits, an undercurrent condition (indicating some other form of equipment fault).

In AC systems, these electrical current sensors have typically been designed as current transformers (CTs). In a CT, an alternating current flowing through a primary winding or coil induces current to flow through a secondary winding or coil due to its time-varying magnetic flux. A magnetic core, such as a ferrite or silicon steel core, serves as the winding core or is otherwise positioned within the coils in order to concentrate the magnetic flux and enhance the output power of the secondary coil, which may be used to operate a device such as a protective relay. Recently, some electrical current sensors have been designed as Rogowski coils. In a Rogowski coil, a single winding around an approximately toroidal, non-magnetic core serves as the sensor element. An alternating current flowing through the annular void at the center of the toroid induces current to flow through the Rogowski coil due to its time-varying magnetic flux. Although the Rogowski coil is not able to generate an output power similar to a CT, and consequently must be combined with powered electronics in order to communicate with remote monitoring stations or to operate a relay, the Rogowski coil can effectively reject the influence of external time-varying magnetic fields, sensing only the alternating current carried within power lines routed through the coil's annular void. Thus, Rogowski coils are preferred for use in grid monitoring applications where a monitored transmission or distribution line is likely to be positioned in close proximity to other such lines which might potentially contaminate sensor measurements.

The ability of a Rogowski coil to reject the influence of external time-varying magnetic fields depends upon the uniformity and regularity of the spacing of the coil elements. Although a Rogowski coil does not require a closed toroid, the discontinuity between the ends of the coil presents a potential source of irregularity in the windings and susceptibility to the influence of such external fields. In addition, when a Rogowski coil is to be installed over a live power line, the coil must be flexed or distorted at least at one other point in order to open the ends of the coil and allow the power line to pass through the discontinuity. These sources of difficulty have generally prevented Rogowski coils from being retrofit over live power distribution lines. In contrast to power transmission lines, where individual lines can be taken out of service due to the redundancy and overcapacity designed into regional transmission grids, and protective relay circuits, where specific equipment can be scheduled out of service for upgrade or maintenance, power distribution lines lack redundancy and can serve hundreds or even thousands of separate end-users, including both commercial and residential consumers. Thus, there is a need for a Rogowski-like electrical current sensor which can easily be installed over a live power distribution line, preferably from the ground or from the bucket of a lift truck. In addition, it would be advantageous if the electrical current sensor did not require fine manipulation of its constituent parts or direct manipulation by lineworkers equipped with insulating gloves.

### SUMMARY

Presented is a disassociated split sensor coil and method of manufacturing which produces, in effect, a disassociated split Rogowski coil. The disassociated split sensor coil is suitable for installation over live power distribution lines, such as in retrofit installations of “smart grid” distribution line sensors, and adapted for mounting within a clamshell sensor housing that can be manipulated by a lineworker equipped with a conventional “hot stick” or live line tool. Further objects and advantages of the disclosed coil and method will be apparent from the detailed discussion provided below.

In a first aspect, the disassociated split sensor coil comprises first and second non-magnetic, hemi-toroidal cores. The first and second cores each include a surface channel extending from one end of the hemi-toroidal core to the opposite end of the hemi-toroidal core. A first wire section is wound about the first core to form a first helical coil extending from the one end to the opposite end, with the first helical coil being electrically connected to a first terminal wire proximate the one end and to a first connecting wire proximate the opposite end. The first connecting wire is disposed so as to extend through the surface channel of the first core, under the first helical coil, from the opposite end to at least the first end. A second wire section is wound about the second core to form a second helical coil extending from the one end to the opposite end, with the second helical coil being electrically connected to a second terminal wire proximate the one end and to a second connecting wire proximate the opposite end. The second connecting wire is disposed so as to extend through the surface channel of the second core, under the second helical coil, from the opposite end to at least first end. The first connecting wire and the second connecting wire are electrically connected to each other to form a continuous electrical path from the first terminal wire to the second terminal wire, with the first and second terminal wires being electrically connectable to a monitoring circuit.

In a second aspect, a method of manufacturing a disassociated split sensor coil comprises the steps of (a) obtaining a non-magnetic, hemi-toroidal core having a surface channel extending from one end of the hemi-toroidal core to the opposite end of the hemi-toroidal core, (b) placing a first length of a wire within the surface channel so as to extend from at least the one end to at least the opposite end, (c) winding a second length of the wire about the hemi-toroidal core to form a helical coil section extending from the opposite end to the one end, and (d) providing a third length of the wire extending from the one end, wherein the first, second, and third lengths are sequentially ordered lengths of a contiguous wire. The steps are repeated to form a pair of disassociated split sensor coil elements, with the elements being electrically connectable by joining the first lengths of wire to form the disassociated split sensor coil. Preferably, the first length of wire includes a loop portion disposed between the opposite end of the hemi-toroidal core and the helical coil section, with the first length being drawn out of the surface channel at the one end to draw the loop portion taught at the opposite end of the hemi-toroidal core after the winding of the second length of the wire.

Several additional features, functions, and advantages can be achieved in various embodiments, examples of which can be seen with reference to the following description and drawings.

### BRIEF DESCRIPTION OF THE DRAWINGS

The accompanying figures depict various embodiments of the split sensor coil and manufacturing method. A brief description of each figure is provided below.

FIG. 1A is a plan view of a hemi-toroidal core of the disassociated split sensor coil.

FIG. 1B is an end view of the core of FIG. 1A.

FIG. 2 is a plan view of the hemi-toroidal core of FIG. 1 after winding of a helical coil section about the core.

FIG. 3 is a plan view of the disassociated split sensor coil. The second lengths of wire forming the helical coil sections have been omitted for sake of clarity.

FIG. 4 is a plan view of the split sensor coil of FIG. 5, with the split overmold shown only in phantom lines. The second lengths of wire forming the helical coil sections have been omitted for sake of clarity.

FIG. 5 is a plan view of the disassociated split sensor coil after encasement within a split overmold.

FIG. 6 is a sectional view of an overmold portion.

FIG. 7 is a perspective view of the disassociated split sensor coil and split overmold within an exemplary clamshell sensor housing. The housing is shown only in phantom lines for sake of clarity.

FIG. 8 illustrates the steps of a method of manufacturing the disassociated split coil sensor.

### DETAILED DESCRIPTION

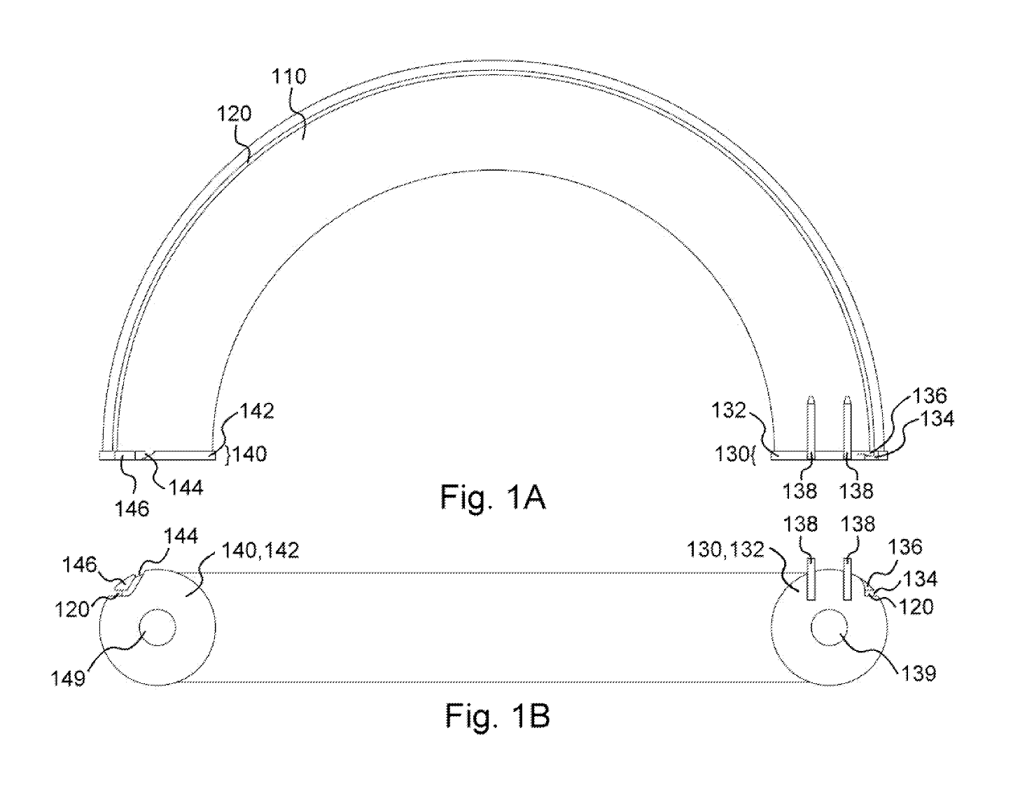

With initial reference to FIGS. 1A and 1B, a disassociated split sensor coil 100 adapted for installation on a live power distribution line is constructed over a pair of non-magnetic, generally hemi-toroidal cores 110. For the purposes of this application, hemi-toroidal shall mean a half of a toroid which has been divided across a radial axis of symmetry, as opposed to a partial toroid formed by a truncated closed curve. Each core 110 includes a surface channel 120 extending from one end, 130, of the hemi-toroidal core to the opposite end, 140, of the hemi-toroidal core. The surface channel 120 is preferably configured with a depth sufficient to allow a wire to be disposed below the surface of the core 110, as further described below. In various embodiments, such as the one illustrated in FIG. 1, the one end 130 of the core 110 may include a flange 132 and a notch 134 including a hook element 136. The flange 132 may serve as a means for registering a start/stop point for a winding machine or locating an end winding in a helical sensor coil (not shown in FIG. 1). The notch 134 and hook element 136 may be disposed proximate the surface channel 120 and configured to receive a wire leaving the surface channel 120, as further described below. In the same or other embodiments, the opposite end 140 of the core may include a flange 142 and a notch 144 including a hook element 146. The flange 142 may also serve as a means for registering a start/stop point for a winding machine or locating an end winding in a helical sensor coil. The aperture 144 and hook element 146 may be disposed proximate the surface channel 120 and configured to receive a wire transitioning from the helical sensor coil into the surface channel 120, as further described below. In some embodiments, the flange 132 may mount a pair of connecting pins 138. The pair of connecting pins 138 may serve as a header for connecting the wires disposed within and around the core 110 to a cable electrically connected to sensor electronics and an opposing portion of the disassociated split sensor coil 100. Also, in some embodiments, both the one end 130 and the opposite end 140 of the core 110 may include recesses 139, 149. The recesses 139 and 149 may be used to hold the core 110 during winding of a wire about the outer surface of the core, as well as to hold the core during the manufacture of an overmold as further described below.

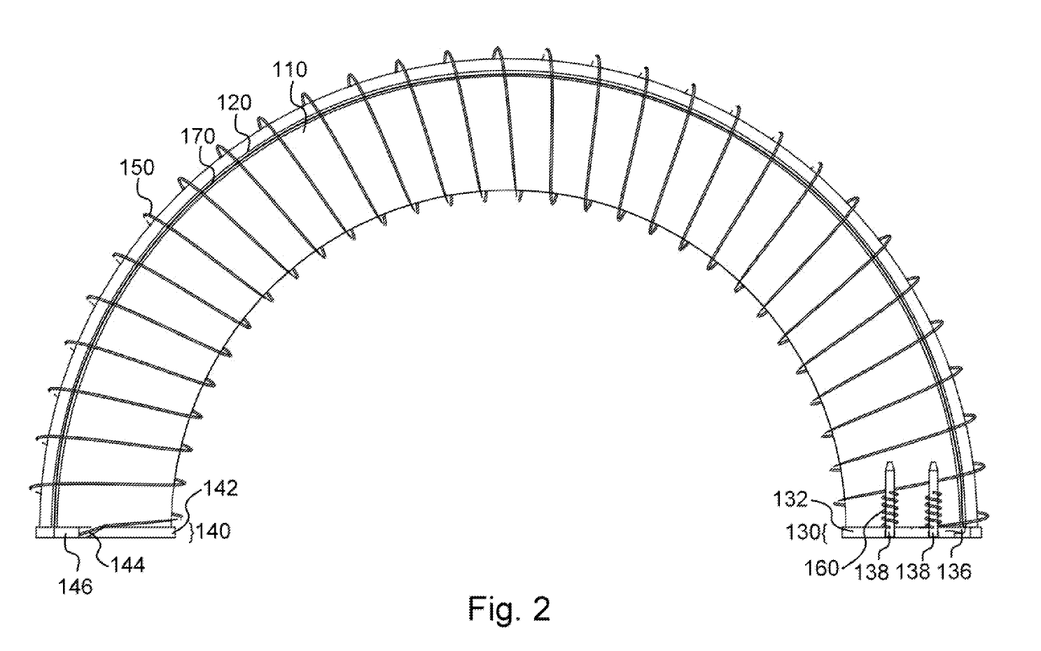

Turning to FIG. 2, the disassociated split sensor coil 100 includes wire sections 150 wound about each core 110 to form a helical coil 152 extending from the one end 130 of the core to the opposite end 140 of the core. The helical coil 152 is electrically connected a terminal wire 160 proximate the one end 130. Preferably, the terminal wire 160 is an additional, contiguous section of the wire section 150 that may form a lead for connection to monitoring circuitry or be connected to one of the pair of pins 138. In other embodiments, the terminal wire 160 may be a separate wire that is soldered to or otherwise electromechanically bonded to the wire section 150 proximate the one end 130. The helical coil 152 is also electrically connected a connecting wire 170 proximate the opposite end 140, with the connecting wire 170 being disposed so as to extend under the helical coil 152 and through the surface channel 120 from the opposite end 140 to at least the one end 130. Preferably, the connecting wire 170 is an additional, contiguous section of the wire section 150 which is looped around the opposite end 140, such as through notch 144 and hook element 146, and disposed within the surface channel 120 as described. In other embodiments, the connecting wire 170 may be a separate wire that is soldered to or otherwise electromechanically bonded to the wire section 150 proximate the opposite end 140.

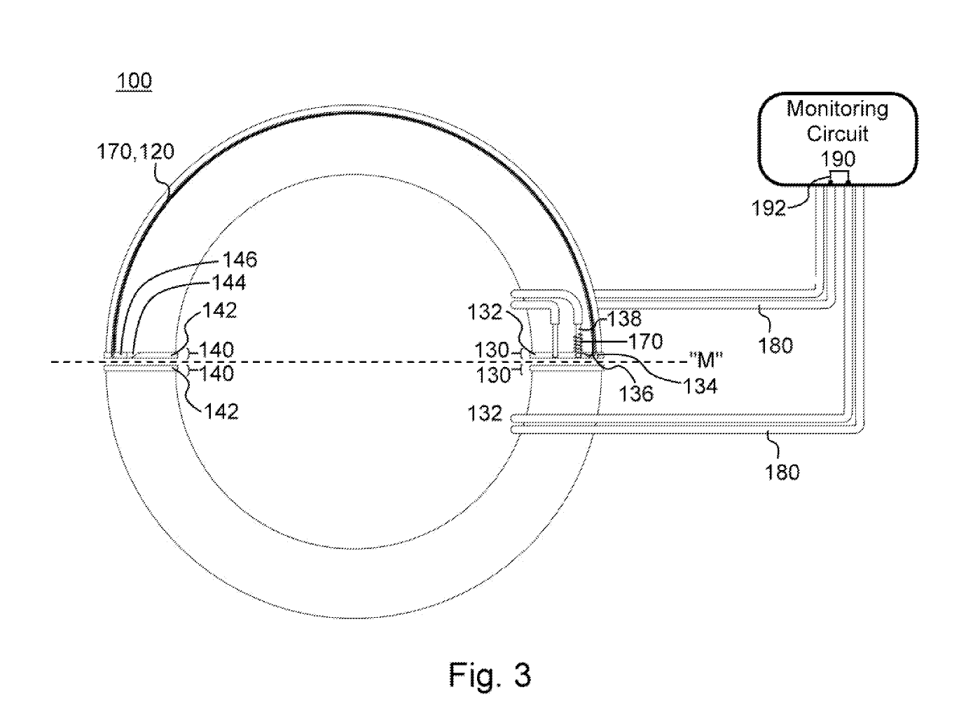

In an exemplary embodiment, shown in FIG. 3, the disassociated split sensor coil 100 comprises two such hemi-toroidal elements, each including a core 110, helical coil 152 (not shown), terminal wire 160, connecting wire 170, and other illustrated elements. The terminal wires 160 are electrically connectable to a monitoring circuit 190, most typically a voltage monitoring circuit including an integrator in order to reconstruct the sensed current waveform magnitude and frequency, via, for example, a multiconductor cable 180 electrically connected to the pair of pins 138 provided on the flange 132 of the one end. The monitoring circuit 190 may provide a conductive path 192 interconnecting the conductors of the cables 180 which are electrically connected to the connecting wires 170 to interconnect the two elements of the disassociated split sensor coil 100. Alternately, a separate flexible cable (not illustrated) may provide a conductive path interconnecting the connecting wires 170 to interconnect the two elements of the disassociated split sensor coil 100. As a result, both elements of the disassociated split sensor coil 100 may be separated from one another across a midline “M” of the disassociated split sensor coil, permitting the sensor to be installed on a live power distribution line without distortion of the coil elements.

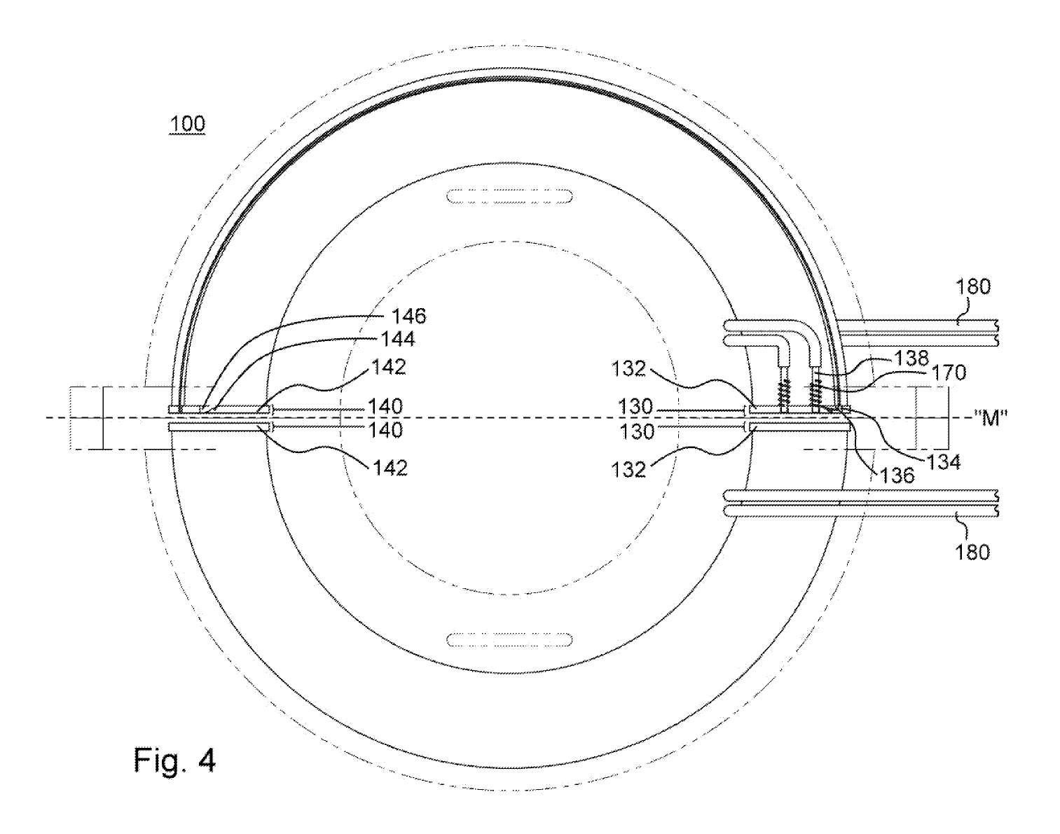

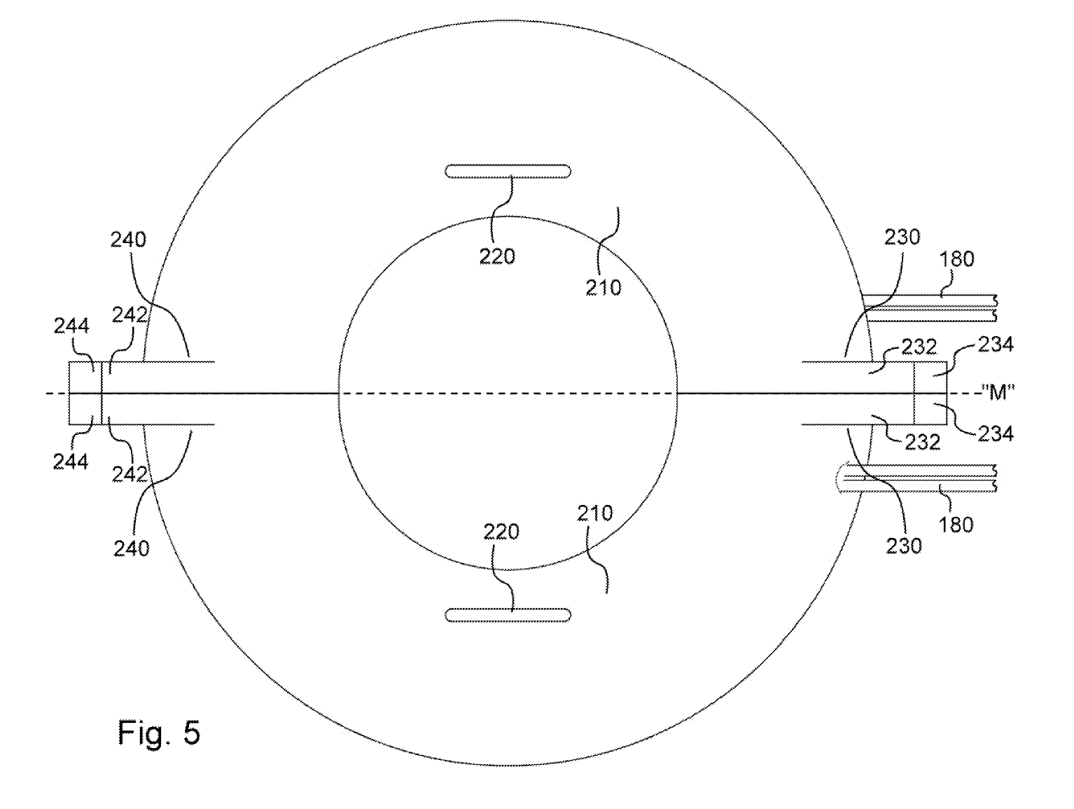

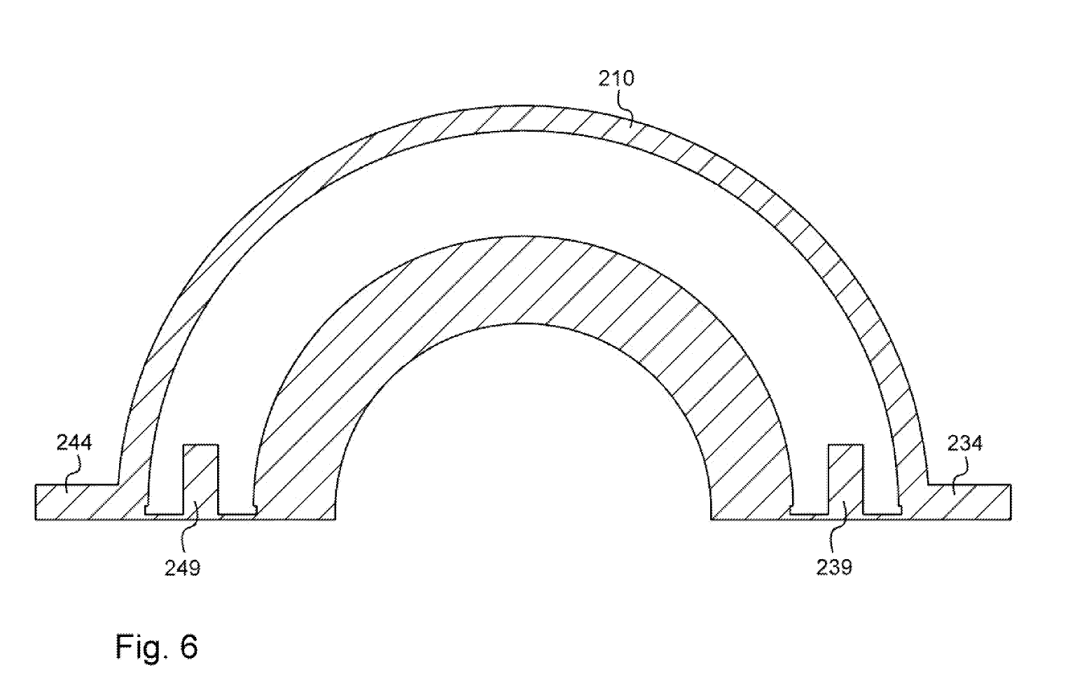

In further exemplary embodiments, shown in FIGS. 4-6, the hemi-toroidal elements of the disassociated split sensor coil 100 are embedded within overmold portions 210. Each overmold portion 210 may itself be a hemi-toroidal structure formed from an electrically insulating material such as polybutylene terephthalate/polycarbonate (PBT+PC) resin. For example, the overmold portion may be formed from Valox® 553, a fiber-reinforced PBT+PC marketed by SABIC Americas, Inc. of Houston, Tex. The surface of the overmold portion 210 may include one or more detent projections 220 for engagement with a detent latch in a sensor housing. The ends 230, 240 of the overmold portion 210 may also include flanges 232 and 242 for seating upon support surfaces in a sensor housing. In addition, each flange 232, 242 may also include a narrowed, outwardly protecting tab portion 234, 244 for insertion between a pair of guides or ribs provided in a sensor housing. The combination of the flange 232, 242 and tab portion 234, 244 may, upon engagement with the housing structure, thereby resist rotation, radial movement (movement within the plane of the toroid) and longitudinal movement (movement perpendicular to the plane of the toroid) with respect to the housing. The ends 230, 240 of the overmold portion 210 may also include projections 239, 249. In embodiments where core 110 includes recesses 139, 149, projections 239 and 249 may be formed by backfilling the recesses 139, 149 with an electrically insulating material. The material may be the same as the material forming the balance of the overmold portion 210, or may be a different electrically insulating material more suitable for manual application into the recesses 139 and 149. The projections 239 and 249 may seal the ends 230, 240 and/or flanges 232, 242 of the overmold to prevent the accumulation of moisture or other contaminants within recesses 139 and 149.

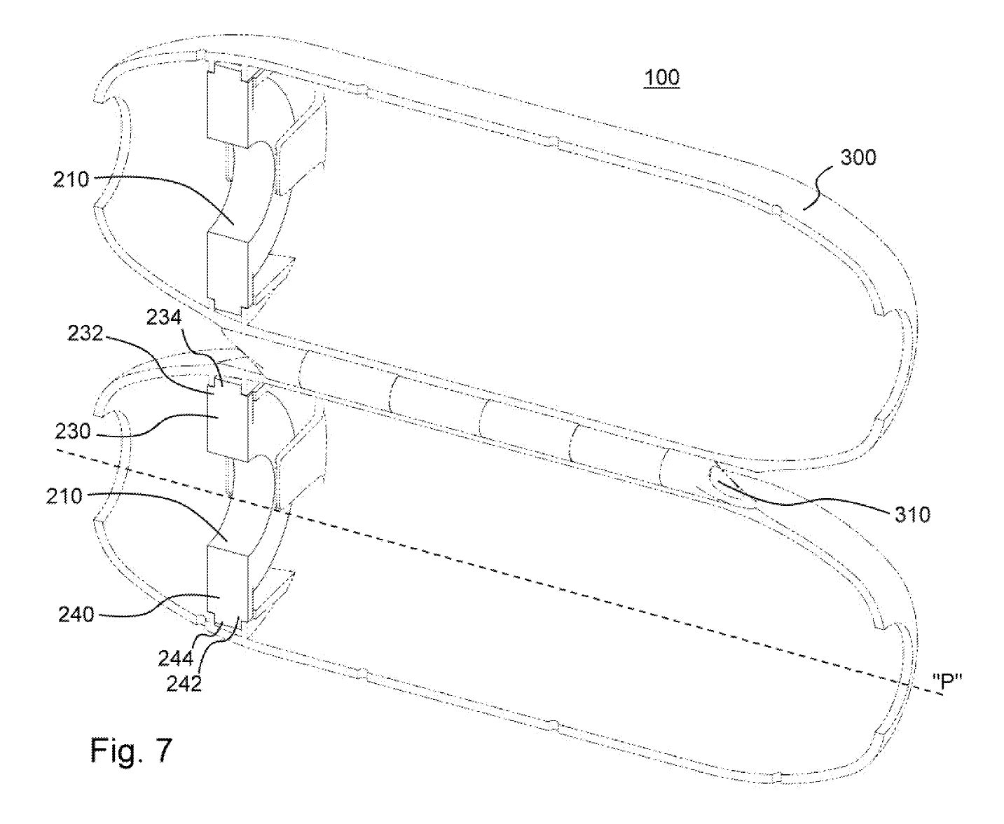

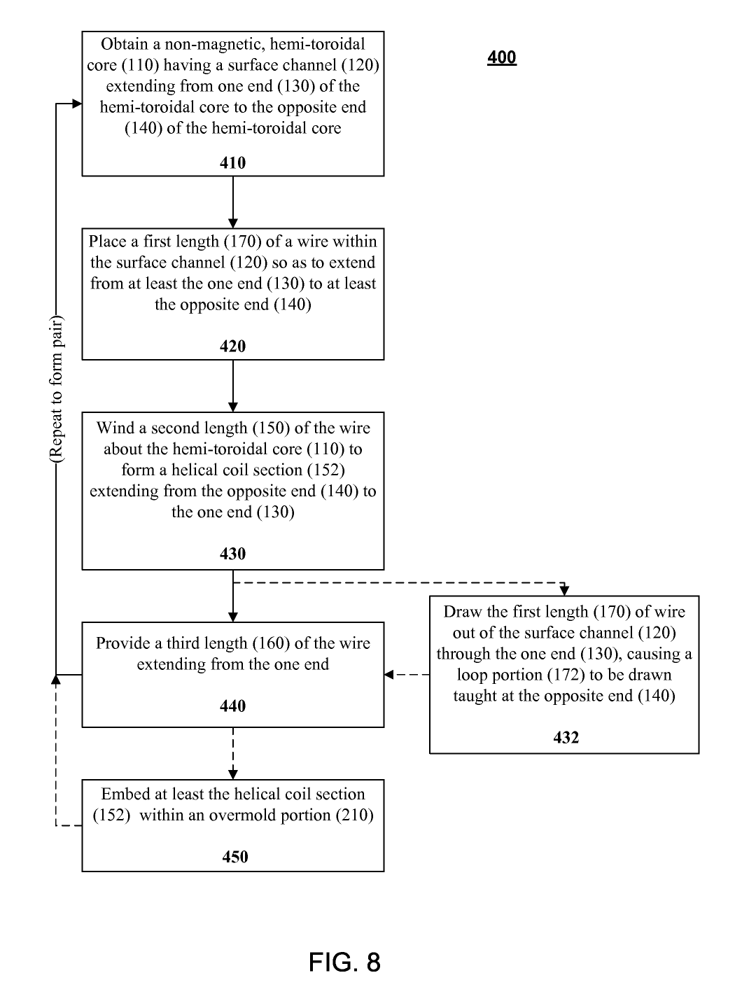

As shown in FIG. 7, in some exemplary embodiments the disassociated split sensor coil 100 (optionally embedded within overmold portions 210) may be mounted within a clamshell sensor housing 300 that can be manipulated by a lineworker to mount the disassociated split sensor coil on a live power distribution line (not illustrated, but coaxially disposed along axis “P”). The clamshell sensor housing 300 may pivot about a hinge mechanism 310 to position the disassociated split sensor coil 100 about a power distribution line, with the ends of the disassociated split sensor coil 100 being separated by small and well-defined discontinuities between the one ends 130 and opposite ends 140, respectively, of the hemi-toroidal cores 110. When embedded within overmold portions 210, the ends of the disassociated split sensor coil 100 will still remain separated by small and well-defined discontinuities between the one ends 130 and opposite ends 140, respectively, of the hemi-toroidal cores 110 and, potentially, a thin layer of overmold formed as part of the flanges 232 and 242 disposed at such ends. In either form, it is notable that the sensor coils 152 are neither distorted nor deformed during the installation process, and that the geometry and width of the discontinuities between the sensor coils 152 may be well-controlled due to the structure of the cores 110. The overmold portions 210 surrounding the sensor coils 152 also advantageously provides electrical isolation and environmental protection for the coils. The clamshell sensor housing 300 may be held closed or drawn closed by various mechanisms, such as a snap-fit latch (not shown) disposed on the separable portions of the sensor housing opposite the hinge mechanism 310 or, more preferably, a screw-driven clamp (also not shown) engageable by a lineworkers “hot stick” device. Other forms of sensor housing and other closure mechanisms will be apparent to those of skill in the art, and are not considered to be critical elements of the disassociated split sensor coil 100 itself as disclosed herein.

Various methods may be employed to manufacture the split sensor coil 100. In some embodiments, a method 400 of manufacturing includes the steps of: obtaining a non-magnetic, hemi-toroidal core 110 having a surface channel 120 extending from one end, 130, of the hemi-toroidal core to the opposite end, 140, of the hemi-toroidal core, 410; placing a first length 170 of a wire within the surface channel 120 so as to extend from at least the one end 130 to at least the opposite end 140, 420; winding a second length 150 of the wire about the hemi-toroidal core to form a helical coil section 152 extending from the opposite end 140 to the one end 130, 430; and providing a third length 160 of the wire extending from the one end 130, 440. The winding of the second length 150 of wire may be performed manually, but is preferably performed by a coil winding machine. As indicated above, the hemi-toroidal core 110 may include a flange 132 disposed at the one end and a flange 142 disposed at the opposite end, whereupon the flange 142 may be used to register a start location with the coil winding machine and the flange 132 may be used to register a stop location with the coil winding machine. To ease manufacturing using a coil winding machine, the first length 170 of wire may include a loop portion 172 disposed between the opposite end 140 of the hemi-toroidal core 110 and the start of the helical coil section 152. The loop portion 172 allows for manipulation of the wire into position within the coil winding machine, easing the winding process. After winding of the helical coil section 152, the method may include the step of drawing the first length 170 of wire out of the surface channel 120 through the one end 130, causing the loop portion 172 to be drawn taught at the opposite end 140, 432—most specifically, against the hook element 146 within notch 144. This step 432 both advantageously secures the loop portion 170 at the opposite end 140 and yields a device having a helical coil section 152, terminal wire 160, and connecting wire 170 of consistent length (as measured from the one end 130 or any other consistently applied baseline, such a predetermined lead length) formed from a single contiguous wire.

The method 400 of manufacturing may further include the step of embedding at least the helical coil section 152 within an overmold portion 210, 450. Prefereably, the step 450 embeds all the helical coil section 152, flange 132 and flange 142 within the overmold portion 210. More preferably, the step 450 forms a flange 232 on one end 230 of the overmold portion 210 and a flange 242 on the opposite end 240 of the overmold portion. Most preferably, the flanges 232, 242 of the overmold portion are formed at and over the flanges 132, 142 of the hemi-toroidal core 110. Although flanges like the flanges 232, 242 may be formed elsewhere on the overmold, flanges provided in this position advantageously provide the greatest control over the geometry and width of the discontinuities between the sensor coils 152.

The steps 410 through 440 or 450 are repeated to form a pair of disassociated split sensor coil elements, with the elements being electrically connectable as described earlier. The method may further include the step of positioning the disassociated split sensor coil 100 within a sensor housing, e.g., clamshell sensor housing 300, such that the one ends 130 are mechanically disposable in a mutually opposing and abutting relationship and the opposite ends 140 are mechanically disposable in a mutually opposing and abutting relationship. However, it will be recognized that such a step is more strictly a configuration step than a manufacturing step. The reader will also recognize that the term “abutting relationship” is intended to encompass circumstances in which a the ends 130, 140 of the hemi-toroidal cores 110 are components of the ends 230, 240 of overmold portions 210, such that a thin layer of overmold material, e.g., 0.02 inches may be interposed between the respective ends.

The embodiments of the invention shown in the drawings and described above are exemplary of numerous embodiments that may be made within the scope of the appended claims. It is contemplated that numerous other configurations recombining individual features or elements of the disclosed embodiments may be created by taking advantage of the disclosure as a whole. It is the applicant's intention that the scope of the patent issuing herefrom will be limited only by the scope of the appended claims.

What is claimed is:

1. A disassociated split sensor coil for installation on a live power distribution line, the disassociated split sensor coil comprising:
first and second non-magnetic, hemi-toroidal cores, each core including a surface channel extending from one end of the hemi-toroidal core to the opposite end of the hemi-toroidal core;
a first wire section wound about the first core to form a first helical coil extending from the one end to the opposite end, wherein the first helical coil is electrically connected to a first terminal wire proximate the one end and to a first connecting wire proximate the opposite end, and wherein the first connecting wire is disposed so as to extend through the surface channel of the first core, under the first helical coil, from the opposite end to at least the first end;
a second wire section wound about the second core to form a second helical coil extending from the one end to the opposite end, wherein the second helical coil is electrically connected to a second terminal wire proximate the one end and to a second connecting wire proximate the opposite end, and wherein the second connecting wire is disposed so as to extend through the surface channel of the second core, under the second helical coil, from the opposite end to at least first end;
wherein the first connecting wire and the second connecting wire are electrically connected to each other to form a continuous electrical path from the first terminal wire to the second terminal wire, and the first and second terminal wires are electrically connectable to a voltage monitoring circuit

2. The disassociated split sensor coil of claim 1, wherein the surface channels are configured with a depth sufficient to allow the first and second connecting wire to be disposed below the surface of the first and second core, respectively.

3. The disassociated split sensor coil of claim 1, wherein the one end of the first core includes a flange providing a notch and a hook element disposed proximate the surface channel and configured to receive the first connecting wire.

4. The disassociated split sensor coil of claim 3, wherein the opposite end of the first core includes a flange providing a notch and a hook element disposed proximate the surface channel and configured to receive the first terminal wire.

5. The disassociated split sensor coil of claim 3, wherein the flange of the one end mounts a pair of connecting pins electrically connected to the first connecting wire and the first terminal wire, respectively.

6. The disassociated split sensor coil of claim 1, wherein the first connecting wire and the second connecting wire are interconnected by a flexible cable, whereby the first and second hemi-toroidal cores may be separated from each other across a midline for installation over a power distribution line without distortion of the first and second helical coils.

7. The disassociated split sensor coil of claim 1, wherein the first hemi-toroidal core and first helical coil are embedded within a first overmold portion, and the second hemi-toroidal core and second helical coil are embedded within a second overmold portion.

8. The disassociated split sensor coil of claim 7, wherein the ends of the overmold portions include flanges for seating upon support surfaces in a sensor housing.

9. The disassociated split sensor coil of claim 8, wherein the flanges include a narrowed, outwardly projecting tab for insertion between a pair of guides in a sensor housing.

10. The disassociated split sensor coil of claim 1, wherein the one end of the first hemi-toroidal core and the opposite end of the first hemi-toroidal core each include a recess, whereby the first hemi-toroidal core may be held by projections extending into the recesses.

11. The disassociated split sensor coil of claim 1, further comprising a clamshell sensor housing, wherein the first hemi-toroidal core is mounted in a first pivotable portion of the clamshell sensor housing and the second hemi-toroidal core is mounted in a second pivotable portion of the clamshell sensor housing, wherein the one ends of the first and second hemi-toroidal cores are positioned proximate to each other upon closure of the clamshell sensor housing, and wherein the opposite ends of the first and second hemi-toroidal cores are positioned proximate to each other upon closure of the clamshell sensor housing.

12. A method of manufacturing a disassociated split sensor coil comprising the steps of:
(a) obtaining a non-magnetic, hemi-toroidal core having a surface channel extending from one end of the hemi-toroidal core to the opposite end of the hemi-toroidal core;
(b) placing a first length of a wire within the surface channel so as to extend from at least the one end to at least the opposite end;
(c) winding a second length of the wire about the hemi-toroidal core to form a helical coil section extending from the opposite end to the one end; and
(d) providing a third length of the wire extending from the one end, wherein the first, second, and third lengths are sequentially ordered lengths of a contiguous wire;
wherein the steps are repeated to form a pair of split sensor coil elements, with the elements being electrically connectable by joining the first lengths of wire to form the split sensor coil.

13. The method of claim 12, wherein the first length of wire includes a loop portion disposed between the opposite end of the hemi-toroidal core and the helical coil section, and the first length is drawn out of the surface channel at the one end to draw the loop portion taught at the opposite end of the hemi-toroidal core after the winding of the second length of the wire.

14. The method of claim 12, wherein the hemi-toroidal core includes a first flange disposed at one end, with the first flange registering a start location for a coil winding machine.

15. The method of claim 14, wherein the hemi-toroidal core includes a second flange disposed at the opposite end, with the second flange registering a stop location for a coil winding machine.

16. The method of claim 12, further comprising the step of embedding at least the helical coil section within an overmold portion.

17. The method of claim 16, wherein the hemi-toroidal core includes a first flange disposed at one end of the hemi-toroidal core and a second flange disposed at the opposite end of the hemi-toroidal core, and the embedding step includes embedding the first and second flanges within the overmold portion.

18. The method of claim 16, wherein the embedding step forms a flange at one end of the overmold portion and a flange at the opposite end of the overmold portion.

19. The method of claim 12, further comprising the step of mounting each hemi-toroidal core in a separate pivotable portion of a clamshell sensor housing, wherein the one ends of the first and second hemi-toroidal cores are positioned proximate to each other upon closure of the clamshell sensor housing, and wherein the opposite ends of the first and second hemi-toroidal cores are positioned proximate to each other upon closure of the clamshell sensor housing.
